(19) United States
(12) Patent Application Publication
(10) Pub. No.: US 2026/0215185 A1
(43) Pub. Date: Jul. 23, 2026

(54) SUBSTRATE PROCESSING APPARATUS, SUBSTRATE PROCESSING METHOD, AND SEMICONDUCTOR DEVICE MANUFACTURING METHOD

(71) Applicant: Kioxia Corporation, Tokyo (JP)

(72) Inventors: Katsuaki NATORI, Yokohama (JP); Keyaki MORI, Yokohama (JP); Hiroshi MATSUBA, Fujisawa (JP); Hiroyuki FUKUMIZU, Yokohama (JP)

(73) Assignee: Kioxia Corporation, Tokyo (JP)

(21) Appl. No.: 19/317,816

(22) Filed: Sep. 3, 2025

(30) Foreign Application Priority Data
Jan. 23, 2025 (JP) 2025-010127

(51) Int. Cl. H01L 21/3213; H01J 37/32

(52) U.S. Cl. CPC H10P 50/267; H01J 37/3244; H01J 2237/332; H01J 2237/334

(57) ABSTRACT

A substrate processing apparatus includes a chamber configured to house a substrate, wherein a processing target film is provided on the substrate; a stage provided inside the chamber and placing the substrate; a supplier configured to supply a gas for processing the processing target film into the chamber; a power source configured to apply high-frequency power on the stage; and a film containing tantalum provided on an inner surface that is configured to contact the gas.

### CROSS-REFERENCE TO RELATED APPLICATION

This application is based upon and claims the benefit of priority from Japanese Patent Application No. 2025-010127, filed Jan. 23, 2025, the entire contents of which are incorporated herein by reference.

### FIELD

Embodiments described herein relate generally to a substrate processing apparatus, a substrate processing method, and a semiconductor device manufacturing method.

### BACKGROUND

When dry etching a processing target film on a substrate using a halogen gas, the inside of a chamber may be corroded by the reaction of the halogen gas.

### DESCRIPTION OF THE DRAWINGS

FIG. 1 is a view showing an example of a configuration of a substrate processing apparatus according to a first embodiment.

FIG. 2 is a flowchart showing an operation example of the substrate processing apparatus according to the first embodiment.

FIG. 3 is an explanatory view illustrating etching of platinum in the operation example of the substrate processing apparatus according to the first embodiment.

FIG. 4 is an explanatory view illustrating an operation example of the substrate processing apparatus according to the first embodiment.

FIG. 5 is a graph showing etching rates of tantalum and a compound thereof.

FIG. 6 is a view showing a carbon film deposited on a tantalum film.

FIG. 7 is a graph showing a relationship between a temperature of etching and a thickness of the carbon film deposited on the tantalum film.

FIG. 8 is a view showing a configuration of a substrate processing apparatus according to a first modification example of the first embodiment.

FIG. 9 is a view showing a configuration of a substrate processing apparatus according to a second modification example of the first embodiment.

FIG. 10 is a flowchart showing an operation example of the substrate processing apparatus according to the second modification example of the first embodiment.

FIG. 11 is a flowchart showing a step of removing the carbon film in the operation example of the substrate processing apparatus according to the second modification example of the first embodiment.

FIG. 12 is a view showing an example of a configuration of a substrate processing apparatus according to a second embodiment.

### DETAILED DESCRIPTION

Embodiments provide a substrate processing apparatus, a substrate processing method, and a semiconductor device manufacturing method, which are capable of reducing corrosion inside the apparatus by gases for processing a processing target film.

In general, according to one embodiment, a substrate processing apparatus includes: a chamber configured to house a substrate, wherein a processing target film is provided on the substrate; a stage provided inside the chamber and placing the substrate; a supplier configured to supply a gas for processing the processing target film into the chamber; a power source configured to apply high-frequency power to the substrate processing apparatus; and a film containing tantalum provided on an inner surface that is configured to contact the gas.

Hereinafter, embodiments of the present disclosure will be described with reference to the drawings. The embodiments do not limit the present disclosure. The drawings are schematic or conceptual, and the ratio of each part is not necessarily the same as the actual one. In the specification and drawings, the same reference numerals are given to the same elements as those described above with respect to the previous drawings, and detailed description thereof will be omitted as appropriate.

### First Embodiment

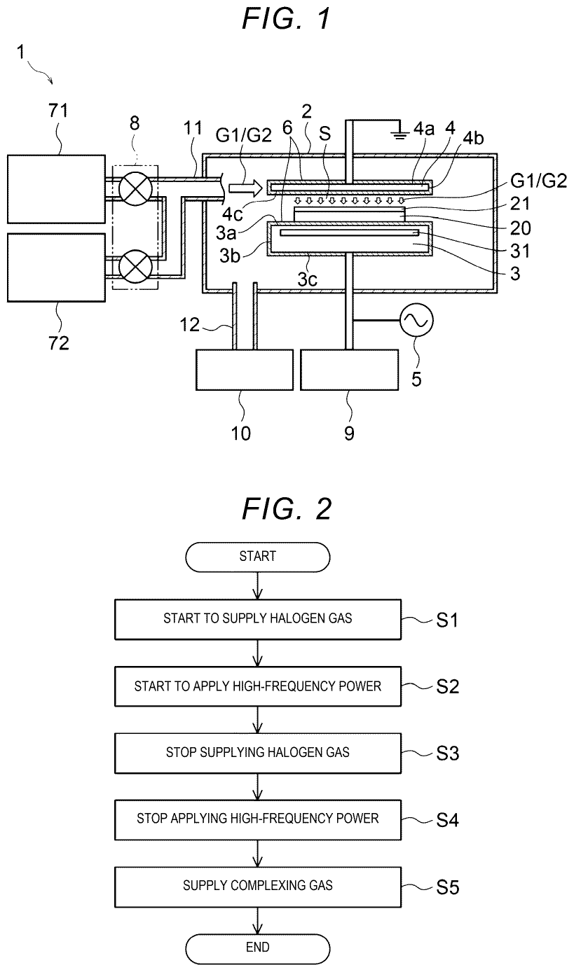

FIG. 1 is a view showing an example of a configuration of a substrate processing apparatus 1 according to a first embodiment. The substrate processing apparatus 1 is an apparatus that dry etches a processing target film 21 provided on a semiconductor substrate 20. The semiconductor substrate 20 is an example of a substrate. The semiconductor substrate 20 is used for manufacturing a semiconductor device. The semiconductor device is, for example, a magnetoresistive random access memory (MRAM). The semiconductor device may be a discrete semiconductor device. For example, the processing target film 21 is used to form a magnetic tunnel junction (MTJ) element of an MRAM. The processing target film 21 may be used to form electrodes of a discrete semiconductor device. In this case, the semiconductor device may be a power device using a compound semiconductor (for example, GaN). For example, the processing target film 21 may be used to form a gate electrode of a GaN-HEMT (High Electron Mobility Transistor).

The substrate processing apparatus 1 includes a chamber 2, a stage 3, a gas supplier 4, a high-frequency power source 5, and a film 6. The chamber 2 is an example of a housing. The stage 3 is an example of a placement unit. The gas supplier 4 is an example of a supplier. The high-frequency power source 5 is an example of an application unit. The substrate processing apparatus 1 further includes a first gas supply source 71, a second gas supply source 72, a gas supply controller 8, a heating power source 9, and a pump 10.

The semiconductor substrate 20 on which the processing target film 21 is provided is housed inside the chamber 2. The processing target film 21 is, for example, a film containing platinum (Pt), and is, for example, a film containing platinum as a main component. The processing target film 21 is, for example, a film of platinum alone. The inside of the chamber 2 is loaded with the semiconductor substrate 20 from the outside of the chamber 2 through a slit (not shown). The chamber 2 is made of a material containing at least one of iron, nickel, and aluminum as a main component, for example. The material that makes up the chamber 2 may be stainless steel (SUS), which contains iron as a main component.

The stage 3 is provided horizontally inside the chamber 2. An upper surface of the stage 3 is on which the semiconductor substrate 20 loaded inside the chamber 2 is placed. The stage 3 is made of a material containing, for example, at least one of iron, nickel, aluminum, boron nitride, silicon nitride, and aluminum nitride as a main component. A heater 31 for heating the semiconductor substrate 20 is provided inside the stage 3. The stage 3 also functions as a lower electrode (that is, a cathode) to which high-frequency power is applied. However, the cathode to which high-frequency power is applied is not limited to the stage 3. The stage 3 may be movable up and down by an actuator (not shown).

The gas supplier 4 supplies a gas for processing the processing target film 21 to the inside of the chamber 2. The gas is a gas having reactivity with the processing target film 21. The gas is a gas for dry etching the processing target film 21. The gas supplier 4 is placed to face the stage 3 with a processing space S interposed therebetween. The gas supplier 4 introduces a gas in a shower-like manner into the processing space S below through a plurality of gas holes. The gas supplier 4 is also called a shower head. The gas supplier 4 also functions as an upper electrode (that is, an anode) grounded.

The first gas supply source 71 supplies a halogen gas G1 containing a halogen element to the gas supplier 4. The first gas supply source 71 is connected to the gas supplier 4 via an intake pipe 11. The first gas supply source 71 supplies the halogen gas G1 to the gas supplier 4 via the intake pipe 11. The halogen gas G1 is, for example, a gas containing fluorine or chlorine. The halogen gas G1 may be HCl. The halogen gas G1 may be one or more substances selected from the group consisting of F₂, Cl₂, ClF, BrF, BrCl, ICl, ClF₃, BrF₃, IF₃, ClF₅, BrF₅, IF₅, IF₇, and I₂Cl₆. The gas supplier 4 supplies the halogen gas G1 supplied from the first gas supply source 71 into the processing space S.

The second gas supply source 72 supplies the gas supplier 4 with a complexing gas G2 that reacts with the metal of the processing target film 21 to form a metal complex having high vapor pressure. The second gas supply source 72 is connected to the gas supplier 4 via the intake pipe 11. The second gas supply source 72 supplies the gas supplier 4 with the complexing gas G2 via the intake pipe 11. The complexing gas G2 is, for example, a β-diketone gas. The β-diketone may be at least one compound selected from the group consisting of dipivaloylmethane, hexafluoroacetylacetone, trifluoroacetylacetone, and acetylacetone. The gas supplier 4 supplies the complexing gas G2 supplied from the second gas supply source 72 into the processing space S.

The gas supply controller 8 controls the supply of the halogen gas G1 from the first gas supply source 71 to the gas supplier 4. In addition, the gas supply controller 8 controls the supply of the complexing gas G2 from the second gas supply source 72 to the gas supplier 4. The gas supply controller 8 is configured with, for example, a mass flow controller that controls a valve and an opening degree of the valve, and the like. The gas supply controller 8 supplies the gas supplier 4 with the complexing gas G2 after the gas supplier 4 is supplied with the halogen gas G1. That is, the gas supplier 4 supplies the halogen gas G1 into the processing space S, and then supplies the complexing gas G2 into the processing space S. By supplying the halogen gas G1 and then supplying the complexing gas G2, a halide of the processing target film 21 can be generated, and the generated halide can be processed (that is, dry etched) by complexing (that is, forming a metal complex).

The high-frequency power source 5 applies high-frequency power to the inside of the chamber 2. The high-frequency power source 5 is electrically connected to the stage 3 via wiring (not shown). The high-frequency power source 5 applies high-frequency power to the stage 3. When high-frequency power is applied to the stage 3, the halogen gas G1 supplied into the processing space S from the gas supplier 4 is excited into plasma.

The high-frequency power source 5 applies high-frequency power when the halogen gas G1 is supplied by the gas supplier 4. By applying high-frequency power when the halogen gas G1 is supplied, the halogen gas G1 can be appropriately excited into plasma. By exciting the halogen gas G1 into plasma, a halide of the processing target film 21 can be generated.

The high-frequency power source 5 does not apply high-frequency power when the gas supplier 4 supplies the complexing gas G2. By not applying the high-frequency power when the complexing gas G2 is supplied, the decomposition of the complexing gas G2 can be prevented. By preventing the decomposition of the complexing gas G2, the halide of the processing target film 21 can be appropriately complexed and processed (that is, dry etched).

The film 6 is provided on an inner surface of the substrate processing apparatus 1 that is in contact with the gases G1 and G2 of the substrate processing apparatus 1. Specifically, the inner surface of the substrate processing apparatus 1 may be a surface of the gas supplier 4 (that is, a surface of the shower head), that is the outer surface. The surface of the gas supplier 4 may be the entire surfaces or a part of an upper surface 4a, a side surface 4b, and a bottom surface 4c excluding the gas supply holes of the gas supplier 4. The part of the upper surface 4a, the side surface 4b, and the bottom surface 4c includes all aspects other than the entire surface of each surface 4a, 4b, and 4c. For example, a part of the upper surface 4a, a part of the side surface 4b, and a part of the bottom surface 4c may be combined with any one or two of the surfaces 4a, 4b, and 4c, a combination of a part of each of the surfaces 4a, 4b, and 4c, or a combination of any one or two of the entire surfaces 4a, 4b, and 4c and a part of the remaining surfaces. In the example shown in FIG. 1, the film 6 is provided over almost the entire surfaces of the upper surface 4a, the side surface 4b, and the bottom surface 4c of the gas supplier 4.

In addition, the inner surface of the substrate processing apparatus 1 may be a surface of the stage 3. The surface of the stage 3 may be the entire surfaces of an upper surface 3a, a side surface 3b, and a bottom surface 3c of the stage 3, or may be a part of the upper surface 3a, the side surface 3b, and the bottom surface 3c of the stage 3. The part of the upper surface 3a, the side surface 3b, and the bottom surface 3c include all aspects other than the entire surface of each surface 3a, 3b, and 3c. For example, a part of the upper surface 3a, the side surface 3b, and the bottom surface 3c may be a combination of any one or two of the surfaces 3a, 3b, and 3c, a combination of a part of each of the surfaces 3a, 3b, and 3c, or a combination of any one or two of the entire surfaces of the surfaces 3a, 3b, and 3c and a part of the remaining surfaces. In the example shown in FIG. 1, the film 6 is provided over almost entire surfaces of the upper surface 3a, the side surface 3b, and the bottom surface 3c of the stage 3.

The surface of the gas supplier 4 in contact with the film 6 contains at least one of iron, nickel, and aluminum as a main component. The surface of the stage 3 in contact with the film 6 contains at least one of iron, nickel, aluminum, boron nitride, silicon nitride, and aluminum nitride as a main component. The film 6 contains tantalum (Ta) as a main component. The film 6 may further contain at least any of silicon (Si), oxygen (O), carbon (C), nitrogen (N), and aluminum (Al). The film 6 includes, for example, at least one of a Ta film, a tantalum silicide (TaSix) film, a tantalum oxide (TaOx) film, a tantalum carbide (TaC) film, a tantalum nitride (TaN) film, a TaSiO₂ film, and a TaAl₂O film. The film 6 containing tantalum has a lower etching rate with respect to dry etching using the halogen gas G1 and the complexing gas G2 as compared to the processing target film 21. Therefore, according to the film 6, the corrosion inside the substrate processing apparatus 1, that is, the etching can be reduced. The details will be described below.

The heating power source 9 is electrically connected to the heater 31 provided on the stage 3 via wiring (not shown). The heating power source 9 generates heat in the heater 31 by supplying power to the heater 31. The semiconductor substrate 20 on the stage 3 is heated by the heater 31 generating heat. By heating the semiconductor substrate 20, the temperature of the semiconductor substrate 20 can be adjusted to a temperature suitable for dry etching.

The pump 10 is connected to the chamber 2 via an exhaust pipe 12. The pump 10 evacuates the gases G1 and G2 in the chamber 2.

Next, an operation example of the substrate processing apparatus 1 having the above-described configuration will be described. FIG. 2 is a flowchart showing an operation example of the substrate processing apparatus 1 according to the first embodiment. In the initial state in FIG. 2, it is assumed that the semiconductor substrate 20 on which a platinum film as the processing target film 21 is provided is placed on the stage 3.

Then, from the initial state, as shown in FIG. 2, the gas supplier 4 starts to supply the halogen gas G1 into the processing space S (step S1) under the control of the gas supply controller 8. The halogen gas G1 is a gas containing a halogen element. The halogen element is chlorine or fluorine. The halogen gas G1 is, for example, HCl gas.

After the supply of the halogen gas G1 is started, the high-frequency power source 5 starts applying high-frequency power to the stage 3 (step S2). The high-frequency power is applied to excite the halogen gas G1 into plasma. After the application of the high-frequency power source 5 is started, the supply of the halogen gas G1 may be started, and the application of the high-frequency power source 5 and the supply of the halogen gas G1 may be started at the same time.

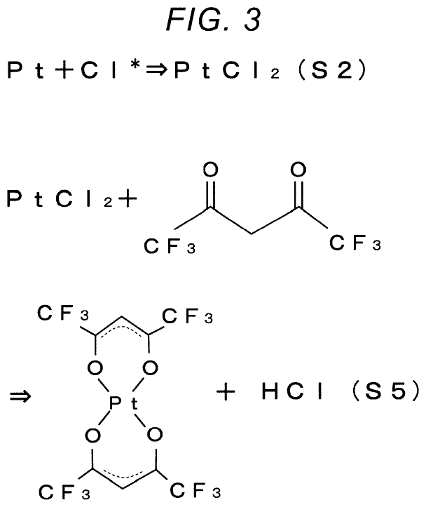

FIG. 3 is an explanatory view showing etching of platinum in the operation example of the substrate processing apparatus 1 according to the first embodiment. FIG. 3 shows an example when a chlorine gas is used as the halogen gas G1. As shown in FIG. 3, the plasma-excited chlorine gas (Cl*) reacts with the platinum (Pt) that constitutes the processing target film 21 to generate platinum chloride (PtCl₂) (step S2). Even when the halogen gas G1 other than a chlorine gas is used, a platinum halide is generated in the same manner as in the case of a platinum chloride.

After a high-frequency power is applied for a predetermined time, as shown in FIG. 2, the gas supplier 4 stops supplying the halogen gas G1 into the processing space S (step S3).

After the supply of the halogen gas G1 is stopped, the high-frequency power source 5 stops applying the high-frequency power to the stage 3 (step S4). After the application of the high-frequency power source 5 is stopped, the supply of the halogen gas G1 may be stopped, or the application of the high-frequency power source 5 and the supply of the halogen gas G1 may be stopped at the same time.

After the application of a high-frequency power is stopped, the gas supplier 4 supplies the complexing gas G2 into the processing space S (step S5). The complexing gas G2 is, for example, a β-diketone gas.

By supplying the β-diketone gas after the application of a high-frequency power is stopped, the β-diketone gas can appropriately react with the platinum chloride without being decomposed. Specifically, as shown in FIG. 3, the β-diketone gas generates bis(hexafluoroacetylacetonato)platinum(II): Pt(hfac)₂, which is a complex, by complexing platinum chloride (step S5). Pt(hfac)₂ is removed from the semiconductor substrate 20 because of the high vapor pressure thereof. Therefore, the processing target film 21 made of platinum can be etched.

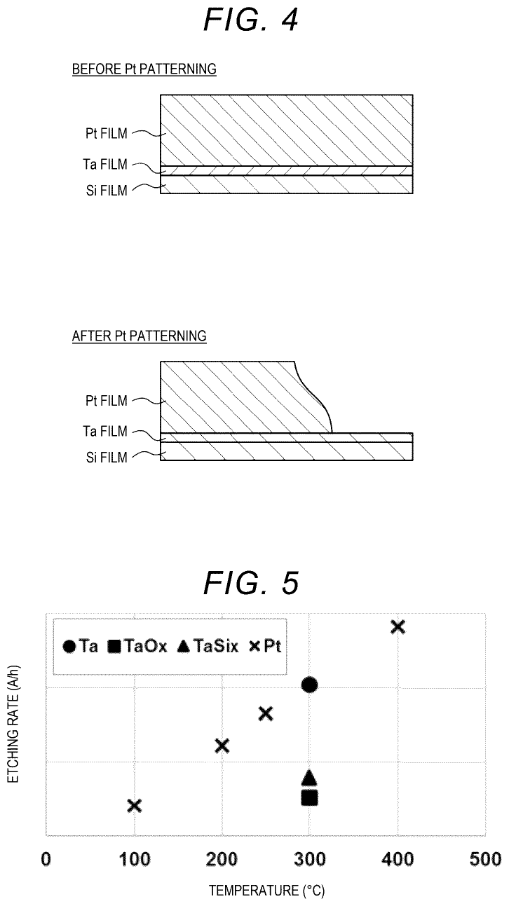

FIG. 4 is an explanatory view showing an operation example of the substrate processing apparatus 1 according to the first embodiment. FIG. 4 schematically shows the experimental result in which the platinum film is patterned by dry etching on a stacked film having a silicon film, a tantalum film on the silicon film, and a platinum film on the tantalum film. In the platinum dry etching, a chlorine gas and a β-diketone gas were used in the method shown in FIG. 2. According to this experiment, as shown in FIG. 4, it was found that the tantalum film under the platinum film is hardly etched after the platinum film is patterned.

FIG. 5 is a graph showing etching rates of tantalum and a compound thereof when supply and plasma excitation of HCl gas, which is one of the halogen gases, and supply of HFA (hexafluoroacetylacetone) gas, which is one of the β-diketone gases, are alternately performed. In FIG. 5, the horizontal axis is the temperature (°C) of the etching. In FIG. 5, the vertical axis is an etching rate (A/h).

As shown in FIG. 5, at 300° C., the etching rates of TaOx (tantalum oxide) and TaSix (tantalum silicide) are smaller than the etching rate of Pt (platinum). Therefore, it is considered that TaOx and TaSix have resistance to HCl gas and HFA and have a corrosion inhibition effect. At 300° C., the etching rate of Pt is approximately the same as the etching rate of Ta.

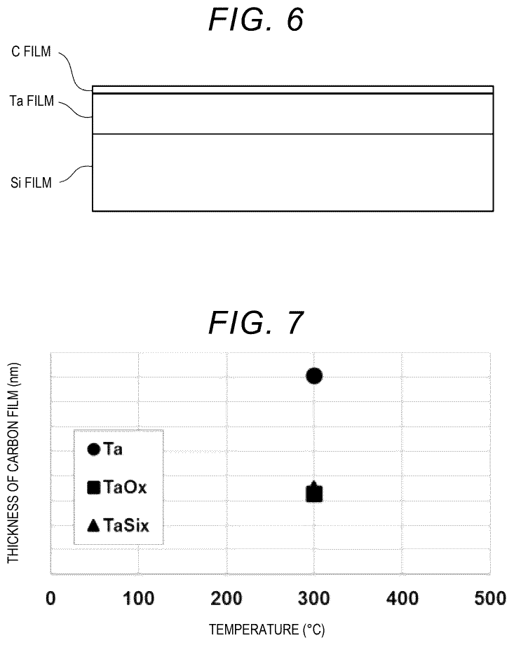

However, as shown in FIG. 4, it is known that the Ta film remains when a Pt film is actually etched. Generally, since the vapor pressure of chloride is high, it is expected that Ta has a higher etching rate than Pt. In contrast to such a general prediction, Ta remained in the experimental results in FIG. 4. Upon examination of the reason why Ta remained, as shown in FIG. 6, it was found that a carbon (C) film was deposited on a tantalum (Ta) film by the decomposition of a β-diketone gas containing carbon, and the etching of the tantalum film was inhibited by a carbon film. The carbon film is an example of a film containing carbon.

FIG. 7 is a graph showing a relationship between an etching temperature (horizontal axis) and a thickness of a carbon film deposited on a tantalum film (vertical axis). That is, as shown in FIG. 7, it is considered that the tantalum (Ta) film can maintain a high corrosion inhibition effect even when the carbon film is deposited on the tantalum film having the corrosion inhibition effect, under a situation where the platinum (Pt) film is etched.

Since the carbon film can be deposited on the tantalum film during the etching process, the etching rate of the tantalum film is lower than the etching rate of the platinum film with respect to the halogen gas such as the chlorine gas and the HCl gas, and the β-diketone gas such as HFA. The similar phenomenon may also occur when a halogen gas other than the chlorine gas and the HCl gas and a complexing gas other than the β-diketone gas are used. Therefore, in the first embodiment, the film 6 containing tantalum is hardly etched even when the platinum film of the semiconductor substrate 20 is etched. Thereby, it is possible to prevent the inner surface of the substrate processing apparatus 1 covered with the film 6 from being etched.

As described above, according to the first embodiment, the substrate processing apparatus 1 includes the chamber 2, the stage 3, the gas supplier 4, the high-frequency power source 5, and the film 6. The chamber 2 houses the semiconductor substrate 20 on which the processing target film 21 is provided. The stage 3 is provided inside the chamber 2 and the semiconductor substrate 20 is placed thereon. The gas supplier 4 supplies a gas for processing the processing target film 21 to the inside of the chamber 2. The high-frequency power source 5 applies high-frequency power to the inside of the chamber 2. The film 6 is provided on the inner surface in contact with the gases G1 and G2 and contains tantalum. Specifically, the film 6 containing tantalum is provided on the surface of the gas supplier 4 and the surface of the stage 3 described above.

As a result, the film 6 can be prevented from being etched when the processing target film 21 is dry etched using the gases G1 and G2, and thus the inner surface on which the film 6 is provided can be prevented from being etched. As a result, it is possible to reduce the corrosion of the inside of the substrate processing apparatus 1 by the gases G1 and G2 for processing the processing target film 21. Since the corrosion inside the apparatus can be reduced, it is possible to reduce the generation of dust and the metal contamination.

A plurality of modification examples shown below may be applied to the substrate processing apparatus 1 according to the first embodiment.

### First Modification Example

Next, a first modification example of the first embodiment in which the film 6 is also provided on the inner surface of the chamber 2 will be described with a focus on differences from the above-described embodiment. FIG. 8 is a view showing an example of a configuration of the substrate processing apparatus 1 according to the first modification example of the first embodiment. In FIG. 1, an example in which the film 6 is provided on the surface of the gas supplier 4 and the surface of the stage 3 is described. Meanwhile, as shown in FIG. 8, the film 6 may be further provided on the inner surface of the chamber 2. The inner surface of the chamber 2 may be the entire surfaces or a part of an inner upper surface 2a, an inner side surface 2b, and an inner bottom surface 2c of the chamber 2. The part of the inner upper surface 2a, the inner side surface 2b, and the inner bottom surface 2c includes all aspects other than the entire surface of each surface 2a, 2b, and 2c. For example, a part of the inner upper surface 2a, a part of the inner side surface 2b, and a part of the inner bottom surface 2c may be a combination of any one or two of the surfaces 2a, 2b, and 2c, a combination of a part of each of the surfaces 2a, 2b, and 2c, or a combination of any one or two entire surfaces of the surfaces 2a, 2b, and 2c and a part of the remaining surfaces. In the example shown in FIG. 8, the film 6 is provided over almost entire surfaces of the inner upper surface 2a, the inner side surface 2b, and the inner bottom surface 2c of the chamber 2.

According to the example shown in FIG. 8, since the film 6 provided on the inner surface of the chamber 2 can be prevented from being etched when the processing target film 21 is etched using the gas, it is possible to prevent the inner surface of the chamber 2 provided with the film 6 from being etched.

In addition, the film 6 may be provided on the entire surface of the inside of the substrate processing apparatus 1 including the inner surface of the exhaust pipe 12 and a support column supporting the stage 3. In this case, since it is not necessary to select a location where the film 6 is formed, it is possible to form the film 6 at once inside the substrate processing apparatus 1 by a film forming process using a tantalum process gas (for example, a PVD method, a CVD method, or the like). Therefore, it is possible to form the film 6 efficiently. The method of forming the film 6 is not limited to a method by film formation using tantalum process gas. For example, the substrate processing apparatus 1 having the film 6 may be manufactured by assembling each component of the substrate processing apparatus 1 in which the film 6 is formed in advance.

### Second Modification Example

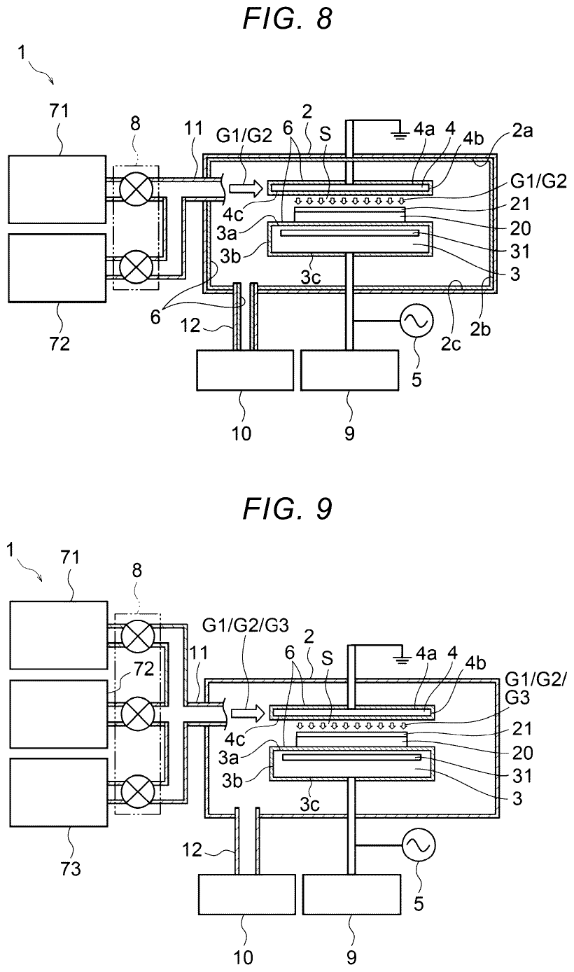

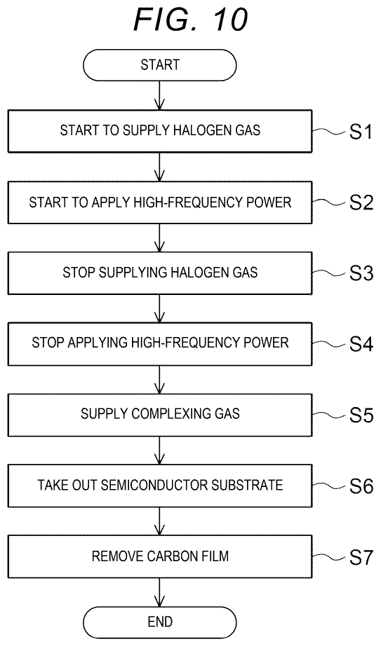

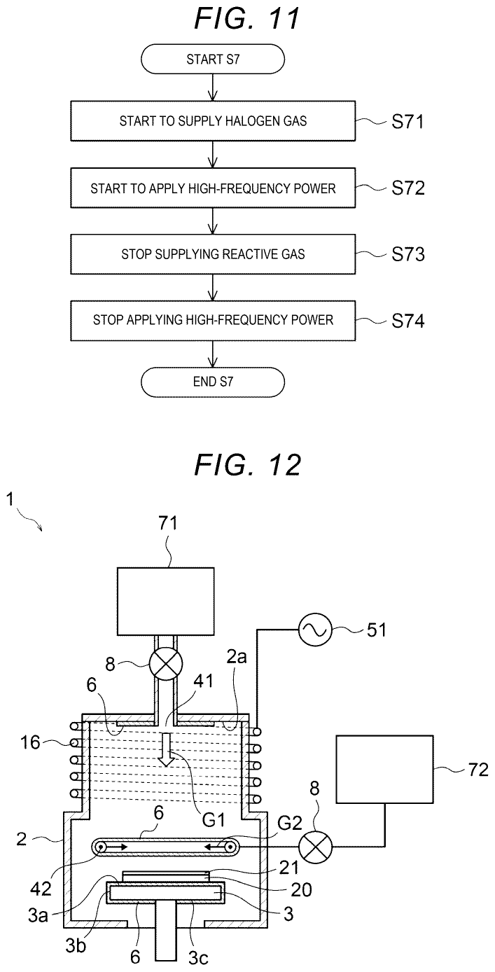

Next, a second modification example of the first embodiment in which a carbon film formed on the film 6 is removed will be described with a focus on differences from the above-described embodiment. FIG. 9 is a view showing a configuration of the substrate processing apparatus 1 according to the second modification example of the first embodiment. FIG. 10 is a flowchart showing an operation example of the substrate processing apparatus 1 according to the second modification example of the first embodiment. FIG. 11 is a flowchart showing a step of removing the carbon film in an operation example of the substrate processing apparatus 1 according to the second modification example of the first embodiment.

As described above, a carbon film is formed on the film 6 provided on the inner surface of the substrate processing apparatus 1 during etching of the processing target film 21. When the thickness of the carbon film is small, the influence on the processing of the new semiconductor substrate 20 is small. On the other hand, when the deposition of the carbon film progresses and the thickness becomes large, the carbon film is peeled off from the surface of the film 6. The peeled carbon film becomes a cause of particles. In order to prevent the generation of particles, the substrate processing apparatus 1 shown in FIG. 9 has a configuration for removing the carbon film formed on the film 6. Specifically, the substrate processing apparatus 1 shown in FIG. 9 further includes a third gas supply source 73 in addition to the configuration shown in FIG. 1. The third gas supply source 73 supplies a reactive gas G3 that reacts with the carbon film to the gas supplier 4 under the control of the gas supply controller 8. The reactive gas G3 is an example of a second gas. The third gas supply source 73 is connected to the gas supplier 4 via the intake pipe 11. The third gas supply source 73 supplies the reactive gas G3 to the gas supplier 4 via the intake pipe 11. The reactive gas G3 is, for example, an oxygen gas. The reactive gas G3 may be nitrogen trifluoride (NF₃) gas.

More specifically, as shown in FIG. 10, the substrate processing apparatus 1 takes out the semiconductor substrate 20 on which the etching of the processing target film 21 is completed to the outside of the chamber 2 by a substrate conveyance mechanism (not shown) (step S6). After the semiconductor substrate 20 on which the etching of the processing target film 21 is completed is taken out, and before the next semiconductor substrate 20 on which the processing target film 21 is provided is housed in the chamber 2, the substrate processing apparatus 1 removes the carbon film formed on the film 6 (step S7).

As shown in FIG. 11, in the removal of the carbon film, first, the gas supplier 4 starts to supply the reactive gas G3 into the processing space S (step S71) under the control of the gas supply controller 8. The reactive gas G3 is, for example, an oxygen gas or a trifluoride gas.

After the supply of the reactive gas G3 is started, the high-frequency power source 5 starts to apply high-frequency power to the stage 3 (step S72). The reactive gas G3 is excited into plasma by applying high-frequency power. When the reactive gas G3 is an oxygen gas, the carbon film is converted into carbon dioxide (CO₂) gas and removed by reacting the carbon film with the plasma-excited oxygen gas. When the reactive gas G3 is a nitrogen trifluoride gas, the carbon film is converted into a tetrafluoromethane (CF₄) gas and removed by reacting the carbon film with the plasma-excited nitrogen trifluoride gas. The supply of the reactive gas G3 may be started after the application of the high-frequency power source 5 is started, or the application of the high-frequency power source 5 and the supply of the reactive gas G3 may be started at the same time.

After a high-frequency power is applied for a predetermined time, the gas supplier 4 stops supplying the reactive gas G3 into the processing space S (step S73).

After the supply of the reactive gas G3 is stopped, the high-frequency power source 5 stops applying the high-frequency power to the stage 3 (step S74). After the application of the high-frequency power source 5 is stopped, the supply of the reactive gas G3 may be stopped, or the application of the high-frequency power source 5 and the supply of the reactive gas G3 may be stopped at the same time.

According to the examples shown in FIGS. 9 to 11, the carbon film deposited on the film 6 can be removed, thus the generation of particles can be prevented. Since the generation of particles can be prevented, the semiconductor substrate 20 to be newly processed in the chamber 2 can be prevented from being contaminated by the particles.

### Second Embodiment

Next, a second embodiment in which the etching of the processing target film 21 is performed using an inductively coupled plasma (ICP) will be described with a focus on differences from the above-described embodiment. FIG. 12 is a view showing an example of a configuration of the substrate processing apparatus 1 according to the second embodiment. As shown in FIG. 12, the substrate processing apparatus 1 according to the second embodiment includes a coil 16 and a high-frequency power source 51 that applies a high-frequency current (power) to the coil 16. This causes high frequency to be applied to the inside of the chamber In addition, in the second embodiment, the gas supplier 4 includes a first supplier 41 that supplies a halogen gas G1 and a second supplier 42 that supplies a complexing gas G2. The first supplier 41 is disposed at an upper end of the inside of the coil 16. In the example shown in FIG. 12, the first supplier 41 is configured with a lower end portion of the intake pipe of the halogen gas G1. The first supplier 41 may be configured as a shower head in the same manner as in the first embodiment. The second supplier 42 is disposed below the coil 16 and above the stage 3. In the example shown in FIG. 12, the second supplier 42 is configured with an annular intake pipe provided with gas holes on an inner periphery.

When a high-frequency current is applied to the coil 16 from the high-frequency power source 51, a magnetic field induced inside the coil 16 changes. That is, the magnetic field acting on the halogen gas G1 introduced into the inside of the coil 16 from the first supplier 41 changes. The halogen gas G1 is excited into plasma by changing the magnetic field. The plasma-excited halogen gas G1 generates a halide of the processing target film 21. The complexing gas G2 supplied from the second supplier 42 complexes the halide of the processing target film 21 to remove (that is, etch) the halide.

In the second embodiment, the film 6 is provided in the vicinity of the first supplier 41, on the surface of the second supplier 42, and on the surface of the stage 3. In the example shown in FIG. 12, the vicinity of the first supplier 41 is a central portion of the inner upper surface 2a of the chamber 2. In addition, in the example shown in FIG. 12, the film 6 is provided over almost the entire surface of the outer peripheral surface of the second supplier 42 excluding the gas holes. In addition, in the example shown in FIG. 12, the film 6 is provided over almost entire surfaces of the upper surface 3a, the side surface 3b, and the bottom surface 3c.

Therefore, also in the second embodiment, since the film 6 can be prevented from being etched when the processing target film 21 is etched using the gases G1 and G2, the inner surface on which the film 6 is provided can be prevented from being etched. As a result, the corrosion of the inside of the apparatus by the gases G1 and G2 for processing the processing target film 21 can be reduced.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A substrate processing apparatus comprising:
a chamber configured to house a substrate, wherein a processing target film is provided on the substrate;
a stage provided inside the chamber and placing the substrate;
a supplier configured to supply a gas for processing the processing target film into the chamber;
a power source configured to apply a high-frequency power to the substrate processing apparatus ; and
a film containing tantalum provided on a surface that is configured to contact the gas.

2. The substrate processing apparatus according to claim 1, wherein
the gas includes a halogen gas and a complexing gas.

3. The substrate processing apparatus according to claim 2, wherein
the halogen gas includes chlorine.

4. The substrate processing apparatus according to claim 2, wherein
the complexing gas includes a β-diketone gas.

5. The substrate processing apparatus according to claim 4, wherein
the β-diketone gas includes a hexafluoroacetylacetone gas.

6. The substrate processing apparatus according to claim 1, wherein
the film containing tantalum further includes at least one of silicon, oxygen, carbon, nitrogen, or aluminum.

7. The substrate processing apparatus according to claim 1, wherein
the surface includes at least one of iron, nickel, aluminum, boron nitride, silicon nitride, or aluminum nitride as a main component.

8. The substrate processing apparatus according to claim 1, wherein
the surface includes a surface of the supplier.

9. The substrate processing apparatus according to claim 1, wherein
the surface includes a surface of the stage.

10. The substrate processing apparatus according to claim 1, wherein
the surface includes an inner surface of the chamber.

11. The substrate processing apparatus according to claim 2, wherein
the supplier configured to supply the halogen gas and then supply the complexing gas, and
the power source configured to apply the high-frequency power when the halogen gas is supplied and does not apply the high-frequency power when the complexing gas is supplied.

12. The substrate processing apparatus according to claim 1, wherein
the processing target film includes platinum.

13. The substrate processing apparatus according to claim 6, wherein
a film containing carbon is further formed on the film containing tantalum.

14. A substrate processing method comprising:
processing a processing target film using a substrate processing apparatus including:
housing a substrate in a chamber, the processing target film is provided on the substrate;
placing the substrate on a stage;
providing a gas for processing the processing target film into the chamber; and
applying a high-frequency power to the substrate processing apparatus; and
wherein a film containing tantalum that is provided on a surface that contacts the gas.

15. The substrate processing method according to claim 14, further comprising:
during the processing of the processing target film, forming a film containing carbon on the film containing tantalum.

16. The substrate processing method according to claim 15, further comprising:
removing the substrate from the chamber after processing the processing target film; and
removing the film containing carbon after the substrate is removed from the chamber and before loading a second substrate to the chamber.

17. The substrate processing method according to claim 16, wherein
the removing of the film containing carbon includes supplying a second gas that reacts with the film containing carbon by the supplier, and applying the high-frequency power by the power source.

18. A semiconductor device manufacturing method comprising:
processing a processing target film using a semiconductor substrate processing apparatus including:
housing a semiconductor substrate including the processing target film in a chamber;
placing the semiconductor substrate on a stage inside the chamber;
supplying a gas for processing the processing target film into the chamber; and
applying a high-frequency power to the substrate processing apparatus; and
wherein a film containing tantalum that is provided on a surface that contacts the gas.
